(19) United States
(12) Patent Application Publication
(10) Pub. No.: US 2018/0276779 A1
(43) Pub. Date: Sep. 27, 2018

(54) Model Determination Devices and Model Determination Methods

(71) Applicant: Hitachi, Ltd., Chiyoda-ku, Tokyo (JP)

(72) Inventors: Gueta Lounell BAHOY, Singapore (SG); Thaw Tar Thein ZAN, Singapore (SG); Akiko SATO, Singapore (SG)

(21) Appl. No.: 15/756,879

(22) PCT Filed: Dec. 18, 2015
(86) PCT No.: PCT/SG2015/050498

§ 371 Date: Mar. 1, 2018

(51) Int. Cl. G06Q 50/28; G06F 17/50; G06Q 10/06; G08G 1/01

(52) U.S. Cl. CPC G06Q 50/28; G06F 17/5009; G08G 1/0112; G06Q 10/067; G06Q 10/06393

(57) ABSTRACT

According to various embodiments, a model determination device may be provided. The model determination device may include: a receiving circuit configured to receive manufacturing data related to a product and carrier data related to transporting the product; and a determination circuit configured to determine a model of an impact of the transporting of the product based on the manufacturing data and based on the carrier data.

### TECHNICAL FIELD

Embodiments relate generally to model determination devices and model determination methods.

### BACKGROUND

Road transportation remains a major transport mode for delivering products due to geographical constraints and economic reasons such as limited transportation infrastructure and lower operational cost. In landlocked states or countries, for example, high-value products are transported between manufacturing plants of same or different countries. It can take long travel hours, passing through several urban and rural roads of different road types such as concrete, unpaved, at varying environmental conditions such as terrain and temperature levels.

U.S. Pat. No. 8,744,822B2 entitled “Pavement condition analysis from modelling impact of traffic characteristics, weather data and road conditions on segments of a transportation network infrastructure” proposes an analysis system and method to model the road condition by processing at least traffic and weather data. A road condition model applies traffic characteristics, weather data, and other input data relevant to road conditions, accounting for heat and moisture exchanges between the road, the atmosphere, and pavement substrate(s) in a pavement's composition, to generate accurate and reliable simulations and predictions of pavement condition states for motorists, communication to vehicles, use by industry and public entities, and other end uses such as media distribution. U.S. Pat. No. 8,744,822B2 focuses on road condition modeling that is mainly affected by weather such a frost development and traffic condition like traffic congestion. It does not take into consideration impacts of the road condition to production risks such as degree of product damage as a result of road surface condition.

U.S. Pat. No. 8,451,140B2 entitled “Monitoring road surface conditions” deals only on monitoring of road condition using bump sensor to detect information about road surface conditions. The road surface condition is based on bump intensity, bump width, bump length and depth. In this patent, bump sensor can be similar to the vibration signals of this proposed patent.

Similarly, US 2012/0078572 A1 entitled as “Road surface condition estimating device and method” involves only monitoring of road condition by estimating undulation on rut of vehicle trajectory.

However, road condition monitoring alone, as exemplified by U.S. Pat. No. 8,451,140B2 and 2012/0078572 A1, is only a part to solving the impact of road surface condition. Other data from manufacturing and logistics data are needed such as product information, incident reports, among others are needed to be able to determine the road condition impact to production risks.

In regards to creating model generation and model selection, as exemplified by U.S. Pat. No. 7,933,762 B2 entitled as “Predictive model generation”, model generation are typically made by first having set of predictor variables and creating several subsets or combinations of these variables to generate models. In such as case the resulting models are similar with each other. In this regard, the selection of similar models becomes straightforward by utilizing a common function to evaluate and compare models. In this way, model selection can be conducted automatically or internally within a system. On the other hand, the model selection can be manual or interactive wherein a user can manually select the model through an interface as shown in other works. In this patent, model generation is made by generating dissimilar models such as statistical-based model and physical-based model. Furthermore, this patent proposes that the model selection can be made based on at least two criteria, one is an internal criteria based on the data source characteristic and another criteria which is based on external user preference.

### SUMMARY

According to various embodiments, a model determination device may be provided. The model determination device may include: a receiving circuit configured to receive manufacturing data related to a product and carrier data related to transporting the product; and a determination circuit configured to determine a model of an impact of the transporting of the product based on the manufacturing data and based on the carrier data.

According to various embodiments, a model determination method may be provided. The model determination method may include: receiving manufacturing data related to a product and carrier data related to transporting the product; and determining a model of an impact of the transporting of the product based on the manufacturing data and based on the carrier data.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments are described with reference to the following drawings, in which:

FIG. 1 shows the modules of a system according to various embodiments;

FIG. 2 shows an embodiment of detailed components of the system;

FIG. 3 shows a flow diagram illustrating an example providing of road impact model selection function according to various embodiments;

FIG. 4 shows a representation of manufacturing and logistics network in database according to various embodiments;

FIG. 5 shows an illustration of providing the impact evaluation function according to various embodiments;

FIG. 6 shows an illustration of a user-interface for monitoring according to various embodiments;

FIG. 7 shows a transition diagram when the first selection dialog is changed;

FIG. 8 shows an illustration of an implementation of a simulation part of road impact map according to various embodiments;

FIG. 9 shows a list of additional functions that can be provided for monitoring and simulation functions for road impact map according to various embodiments;

FIG. 10 shows an illustration of an implementation of the system configuration for various modules according to various embodiments; and

FIG. 11 shows a detailed implementation of the system configuration of FIG. 10 according to various embodiments.

### DESCRIPTION

Embodiments described below in context of the devices are analogously valid for the respective methods, and vice versa. Furthermore, it will be understood that the embodiments described below may be combined, for example, a part of one embodiment may be combined with a part of another embodiment.

In this context, the model determination device as described in this description may include a memory which is for example used in the processing carried out in the model determination device. A memory used in the embodiments may be a volatile memory, for example a DRAM (Dynamic Random Access Memory) or a non-volatile memory, for example a PROM (Programmable Read Only Memory), an EPROM (Erasable PROM), EEPROM (Electrically Erasable PROM), or a flash memory, e.g., a floating gate memory, a charge trapping memory, an MRAM (Magnetoresistive Random Access Memory) or a PCRAM (Phase Change Random Access Memory).

In an embodiment, a “circuit” may be understood as any kind of a logic implementing entity, which may be special purpose circuitry or a processor executing software stored in a memory, firmware, or any combination thereof. Thus, in an embodiment, a “circuit” may be a hard-wired logic circuit or a programmable logic circuit such as a programmable processor, e.g. a microprocessor (e.g. a Complex Instruction Set Computer (CISC) processor or a Reduced Instruction Set Computer (RISC) processor). A “circuit” may also be a processor executing software, e.g. any kind of computer program, e.g. a computer program using a virtual machine code such as e.g. Java. Any other kind of implementation of the respective functions which will be described in more detail below may also be understood as a “circuit” in accordance with an alternative embodiment.

According to various embodiments, a road condition impact may be determined in a distributed manufacturing network.

Road transportation remains a major transport mode for delivering products due to geographical constraints and economic reasons such as limited transportation infrastructure and lower operational cost. In landlocked states or countries, for example, high-value products are transported between manufacturing plants of same or different countries. It can take long travel hours, passing through several urban and rural roads of different road types such as concrete, unpaved, at varying environmental conditions such as terrain and temperature levels.

Examples of traded products are electronic and mechanical parts for automotive and machineries that are prone to physical damage such as dents and chip-offs, agricultural produce that are delicate and easily spoiled, and industrial products such as lubricants and oil that can leak and can be hazardous. Thus, product damages can be assumed to be caused by surface condition of roads.

While it is intuitive to generally speculate that rough roads can impact products while smooth roads are safe from damages, quantitatively evaluating the impact of road condition is not a straightforward process. To be able to evaluate the impact, information from multiple sources from manufacturing and logistics service providers may be required. A product specification can state product threshold, for example, on stress and strain limits; however, these limits can be manifested or not depending on the road condition as well as the interaction of products with the carrier, vehicle and other factors. As such carrier in-transit data, or sensing data while carriers are transporting, are critical to determine the impact of road condition.

A monolithic solution or developing one model of road condition impact that is applicable to possible input data may not be possible. This is because data coming from manufacturing, logistics data and carrier in-transit data are large and of different types such as time-series, discrete, spatial, among others. Also, identifying what factor causes which impact becomes challenging since data relations between product, product damage and other factors like vehicle types are not well understood.

By not taking into consideration the impact of road surface condition, its effect over a distributed manufacturing network cannot be evaluated. The impact from one part of a manufacturing network can have a substantial rippling effect on the other parts of the network.

Existing patents focus on road condition monitoring and modeling. Methods and systems have proposed to evaluate road surface condition, however, systems and methods for quantitatively measuring impacts of road surface condition on products have not been provided yet. In regard to multiple-model generation, a set of predictor variables is defined and several subsets or combinations of these variables are process to generate similar models.

According to various embodiments, devices (for example systems) and methods may be provided for analyzing the impact of road condition to products being transported in a distributed manufacturing network. The road condition impact can be, but is not limited to, product damage, lead time delay, manufacturing capacity loss. These impacts are very important in the operations of manufacturing companies, trucking companies and logistics service providers.

According to various embodiments, devices and methods may be provided which synthesize data sources from at least manufacturing data and carrier in-transit data. Other data such as operation information from logistics data may be desired to evaluate a total key performance index of a distributed network. Environmental data such as temperature, pressure and weather data may also be incorporated to model the impact of road surface conditions.

According to various embodiments, devices and methods for generating dissimilar road impact models depending on the type of collected data collected from manufacturers, logistics service providers and truck carriers may be provided. Examples of dissimilar models include generating statistical, physical-based and signal-based models. From these models, a best fit model is selected based on the data source characteristics and on the input preference of the end-user of this system.

According to various embodiments, by using the selected model, a total key performance index (KPI) of distributed manufacturing considering the road condition impact can be evaluated. The total KPI can be manufacturing yield or lead time. A network consisting of manufacturing plants and road elements are created to represent a network model. The link weights may be based on the KPI adjusted based on the impact of road condition. According to various embodiments, an application module, for example a road impact map application module, for monitoring and simulation may be provided. For manufacturer and logistics service providers, this provides the visibility of the road condition impact to mitigate its impact prior to and during the shipment of products.

According to various embodiments, accurate identification of incidents that are caused only by road conditions may be provided, since significant factors for road impact models are filtered out from non-relevant factors. Also, the time to react when road-condition-related incidents happened may be shortened since manufacturing and logistics data are integrated in one system.

In the following, system modules and external data sources according to various embodiments will be described.

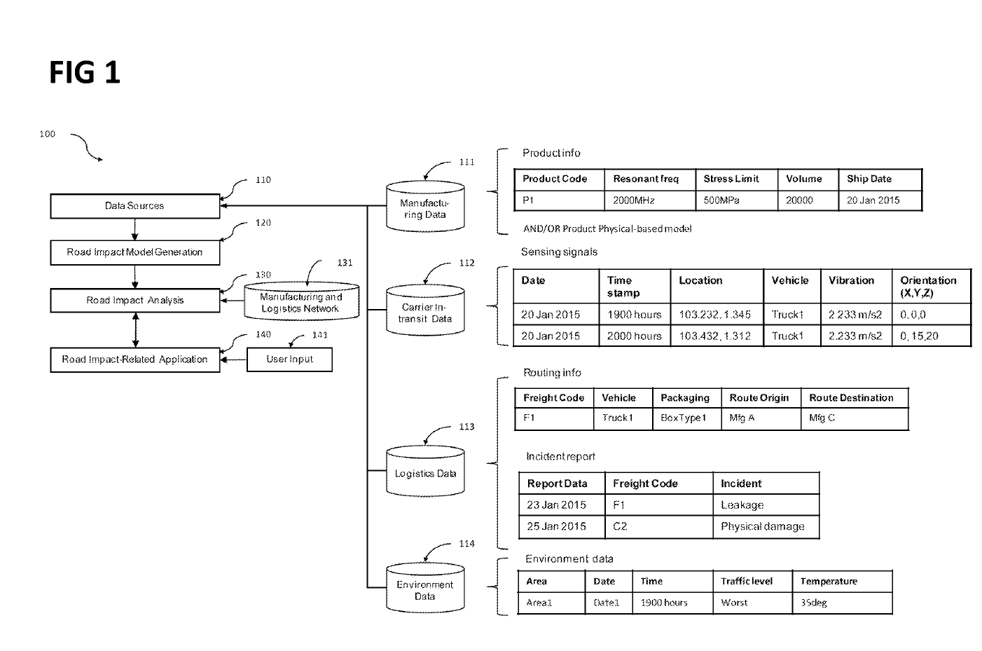

FIG. 1 shows the modules of a system 100 (which may for example be referred to a model determination device) according to various embodiments. A data sources module 110 (which may for example be referred to as a receiving circuit) collects the data coming from multiple sources. Data sources 110 can include data from, but is not limited to, manufacturing data 111, carrier in-transit data 112 (which may also be referred to as carrier data), logistics service data 113 and environmental data 114. The manufacturing data 111 may include product information such as physical dimension, mass, product sensitivity to frequency resonance, stress-strain curve and limits as well as related manufacturing operation parameters such as product volume and shipment date. The carrier in-transit data 112 may include sensing signals such as time-stamped vibration signals, orientation data, location data and other sensing signals. The logistics data 113 may include freight code corresponding to a product, carrier or vehicle type such as trailer truck, related freight information such as packaging, route origin and destination. The environmental data 114 may include temperature and weather data.

Incident data, which is part of the logistics data 113, provides logs of reported incidents such as product damage like leakage and physical dents, substantial delay in delivery, among others. These incidents are mainly road-related or transport-related and may include incidents reported in manufacturing plants, warehouses, among others. In the system, these kinds of incidents can be filtered by comparing the reported time of incident and the time-stamps in the logistics data 113 or the estimated shipment date in the manufacturing data 111. The incident data is critical in the analysis of road condition impact as this can be related to the manufacturing data 111, for example, in comparing the frequency of a specific incidence of a specific product type. In another example, the incident data can be related to sensing signals in the carrier in-transit data 112 to determine the signal characteristics that can have high correlation to a specific incident. The incident data may also be utilized to validate the data correlation between the manufacturing data 111 and the carrier in-transit data 112. An example according to various embodiments is a resonant frequency sensitivity of a product indicated in the manufacturing data 111. In the carrier in-transit data 112, a vibration signal can analyzed using a method like Fast Fourier transform to detect the existence of a resonant frequency. This can be validated by referring to incident reports of an incident relating to a resonant frequency. Moreover, the incident report is important in quantifying the impact of road conditions to manufacturing and logistics. A manufacturing yield loss due to transportation can be calculated by comparing the volume of product damage and the total shipped volume.

At least two data sources from the manufacturing data 111, the carrier in-transit data 112, and the logistics data 113 are processed in impact model generation module 120 (which may be referred to as determination circuit) in order to create generate or update at least one road condition impact model (which may be a model of an impact of transporting a product, and which may be determined based on the manufacturing data and based on the carrier data). The types of data sources are diverse and involve time-series data, discrete values, and CAD (computer aided design) models. This diversity in data source types can be used to create a set of dissimilar impact models for road condition. These set of dissimilar models can be statistical-based, signal-based, physical-based model, and combinations thereof. Depending on collected data, a specific model or set of models are generated or updated.

The collection and updating of the data sources module 110 can be real-time or by batch depending on the frequency of data source updates and on the requirement of a specific application from a user. The updating can depend on the operations of manufacturing and logistics. Some of the data like the manufacturing data 111 may be obtained from manufacturing execution system (MES) present in manufacturing plants. The data collection for the carrier in-transit data 112 can be made by installing special devices to vehicles that are capable of collecting data, and connecting to a communication link to send the data to a server that stores the data sources module 110. According to various embodiments, the opportunity to collect carrier in-transit data may not be too frequent as there can be areas where data updating may not be possible to unavailability of communication network. As such, the collected data can be sent only by batch whenever data updating becomes possible. For the logistics data 113, the transaction points are commonly made at route origin and route destination. Therefore, data updating may only be possible at these points. Hence, data updating from the manufacturing data 111, the carrier in-transit data 112, the logistics data 113, and the environmental data 114 can be asynchronous at various time intervals.

The generation and updating of impact model generation module 120 can be made offline as this can require intensive computational resources. On the other hand, the execution of road impact analysis module 130 and road impact-related application 140 may depend based on a user preference. Therefore, one way of handling the time execution requirement of road impact analysis module 130 and the road impact-related application 140 is to choose a road condition impact model that matches on the user preference.

From these sets of models, a road condition model is selected in road impact analysis module 130. The decision to select a road impact model is based on the characteristics of data sources from 110 and from user input function 141, an external input ingested via the road impact-related application 140. Depending on the specific application in the road impact-related application 140, in particular, the selected key performance index like manufacturing yield and lead time, the impact of road condition is evaluated. This evaluation is conducted over a distributed manufacturing network defined in manufacturing and logistics network database 131.

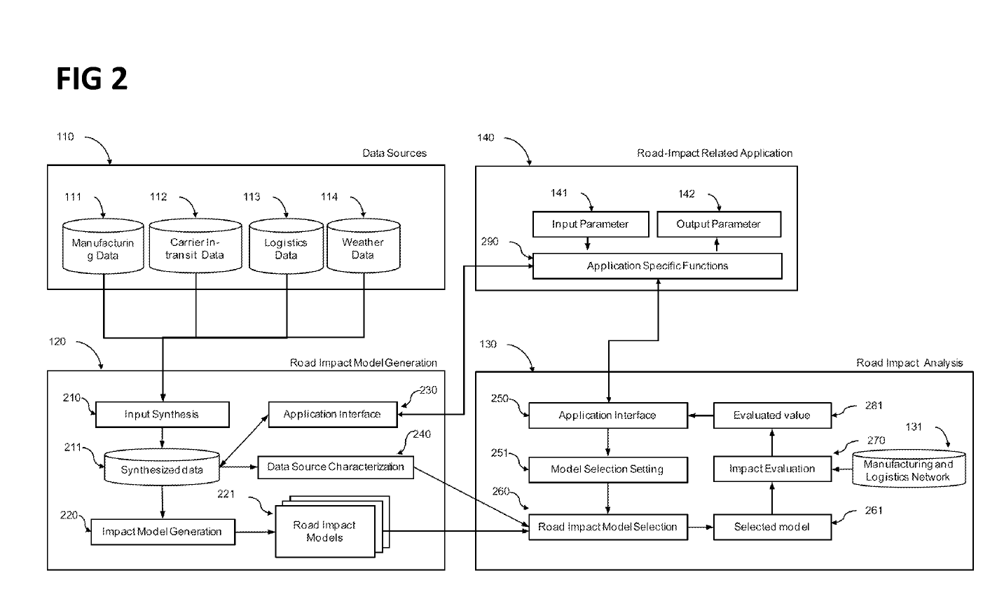

FIG. 2 shows an embodiment of detailed components of the system. Since the data in the data sources module 110 may be referred differently from data sources such as manufacturing data 111, the carrier in-transit data 112, the logistics data 113 and environmental data 114, input synthesis function 210 integrates and synthesizes these data. It may create synthesis table that relates one parameter of one source to another parameter of another source but is referring to same parameter. For example, a particular product code in a manufacturing data may refer to the same product referred to by a specific freight code in logistics data. The synthesized data is then stored in database 211; this database can be updated every time a new data arrives from data sources 110. Since the arrival of data from data sources such as manufacturing data 111, the carrier in-transit data 112, the logistics data 113 and environmental data 114 can be asynchronous, the input synthesis function 210 can have a function that scans through a synthesis table to be able to find the data relations from these data sources (manufacturing data 111, the carrier in-transit data 112, the logistics data 113 and environmental data 114). An example content of a synthesis table is an event setting can be defined by a product that is identified by a product code and linked to a corresponding freight code, a carrier that is assigned to the freight code, and a route associated to the carrier and is identified by route origin and route destination as well as by a route time table.

Synthesized data 211 are used in impact model generation function 220 to generate and update road impact models 221. Function 220 may update the entire set or only a subset (for example of the road impact models). Moreover, the generation and updating of the models can be made offline, or as soon as the data or a batch of the data source is being updated. The application interface function 230 provides an interface for application specific functions such as to read and access data from database 211.

Data source characterization function 240 monitors and analyzes the characteristics of synthesized data 211. The characteristics of data source can be based on a data criterion that may represent closeness of the data to real-world scenario. This criterion can be referred to as data consistency value with value that can range from 0 to 1. The value can be calculated based on references such as data source types, data sample size, and data update timestamps. These references can be weighted depending on their significance. For example, a limited data sample size of sensing signals can be regarded as having low data consistency value. A data source with higher data consistency value can be having multiple-sensing signals, historical data of these signals and incident reports. A data source with high level of consistency value can be a data source having sensing signals, historical data of incidence reports, and CAD representation of data sources module 110.

In road impact analysis module 130, application interface function 250 may receive the user inputs from application module 140 and may output the result of road impact evaluation. One of the inputs may be its user-preference in selecting a road condition impact model, and this input is extracted as model selection setting output 251. In road impact model selection function 260, an impact model is selected based on at least two criteria such as user input preference like execution time requirement, and consistency value of data sources. Based from these criteria, selected model 261 is selected and is used by impact evaluation function 270 to evaluate the manufacturing and logistics network defined in the database 131. The result of the evaluation (which may be an evaluated value 281) is sent back to road-impact related application module 140 via the application interface function 250. It is then processed based on a specific application in Output Parameter 142.

In the following, road surface condition and impact model generation of dissimilar models according to various embodiments will be described.

In impact model generation function 220, impact models can be generated as a function of product damage from sensing signals, incident data, and operation parameters, which can be a frequency of transportation in a specific route, product volume, among others.

According to various embodiments, the impact model generation function 220 may estimate the effect of road surface condition to production risk such as product damage or, in another example, time delay. The road surface condition can be described as good, normal, fair and bad, which are assigned labels from quantitative values. These values can be evaluated based on measurements of features detected from a sensing signal or a combination of signals. An impact of road surface condition can be described in the same way as road surface condition with varying impact levels depending on the percentage of the damage products compared to the total product volume. On the other hand, the impact of road surface condition can be binary values, for example “safe” or “damaged”. If the impact of road surface condition pertains to delivery time, a binary value can also be applied as on-time to delayed, or a set of varying levels of delivery time efficiency. The corresponding values equivalent to the impact of road surface condition may be derived from statistical data or historical data of actual incident data, laboratory test results of product sensitivities, and sensing signal values, among other factors.

The impact model generation function 220 can generate a set of dissimilar models to handle various characteristics of data source. Examples of dissimilar models can be signal-based models, statistical-based models or physical-based models. A straightforward method to model road condition impact is to utilize purely empirical and historical data and conduct statistical analysis. The model is represented as a generalized linear function of a dependent variable against independent variables. The dependent variable can be a percentage of damage products, which can be derived from incident reports in logistics data, and comparing to a total product count being transported. The independent variables can be at least product type, vehicle type. The road surface condition impact may depend on product type since the same road surface condition may have different impact on a set of products. Furthermore, the impact of road surface condition can be different depending on the vehicle type. This can be applicable if vehicle specifications such as suspension system, tire types are not explicitly taken into consideration in the analysis.

A road impact model according to various embodiments can be a signal-based model wherein sensing signals can be used to directly correlate to a road condition impact being measured. In this model, signal features are detected and associated to product damage. The signal features can be signal amplitude, waveforms and signal intensity of specific frequency band. In some cases, these signal features can be derived from laboratory tests. For example, a stress test can be conducted to a product to identify amplitude threshold that causes product damage or the minimum time period of sustained specific signal amplitude that causes product damage. This test can check for availability such as in product specification stating product sensitivity to a resonant frequency. A correlation analysis between features and product damage from incident reports can be conducted to validate signal features and its impact.

A statistical-based model according to various embodiments may be made such that roads can be represented by road type. The classification of road types can be based on calculating a road condition index (RCI). RCI can be similar to international roughness index (IRI) by profiling road surfaces in terms of its roughness or smoothness. Whereas IRI values can be utilized in place of RCI, these values are not available for all roads. RCI can be a practical measurement for the purpose of obtaining representative numerical values to a specific road segment from a set of sensing signals. Conversely, RCI can be viewed as an abstraction of raw signals to achieve smaller data size. For example, sensing signals such as vibration and orientation data have to be sampled at millisecond range to achieve desired accuracy which can entail large memory requirement. By calculating RCI, a road type is assigned to road segments. In effect the RCI can replace the raw sensing data. It will then be used in correlating road condition impact to RCI and other dependent variables.

According to various embodiments, a physical-based model can be generated by creating CAD representations of products, packaging, vehicle surface where the product is placed. In these computer-generated representations, simulated signals can be created based on actual sensing signals from the carrier in-transit data 112. These simulated signals can then be applied in CAD representations. After the simulation, a measurement of impact can be conducted. This physical-based model can be validated by comparing it to empirical data like data in the data sources module 110.

In the following, road impact model selection considering user input preference and data source characteristics according to various embodiments will be described.

In road impact model selection function 260, the selection can be based on at least two criteria such as user preference and data source characteristic. According to various embodiments, a user preference can be a calculation time requirement set out by a user as an input parameter in the user input function 141. On the other hand, a characteristic of a data source can be its data consistency defined in data source characterization function 240. According to various embodiments, sensing signals can only be available in synthesized data 211 which may be assigned with a low data consistency value. In such a case, signal-based model may be appropriate for analysis compared to other models like statistical-based model. For a data source with high data consistency value, road impact analysis can be conducted using statistical-based road impact model. For a data source having a physical-based model and historical data of incidence reports and sensing signals, a physical-based model may be possible for road condition impact evaluation.

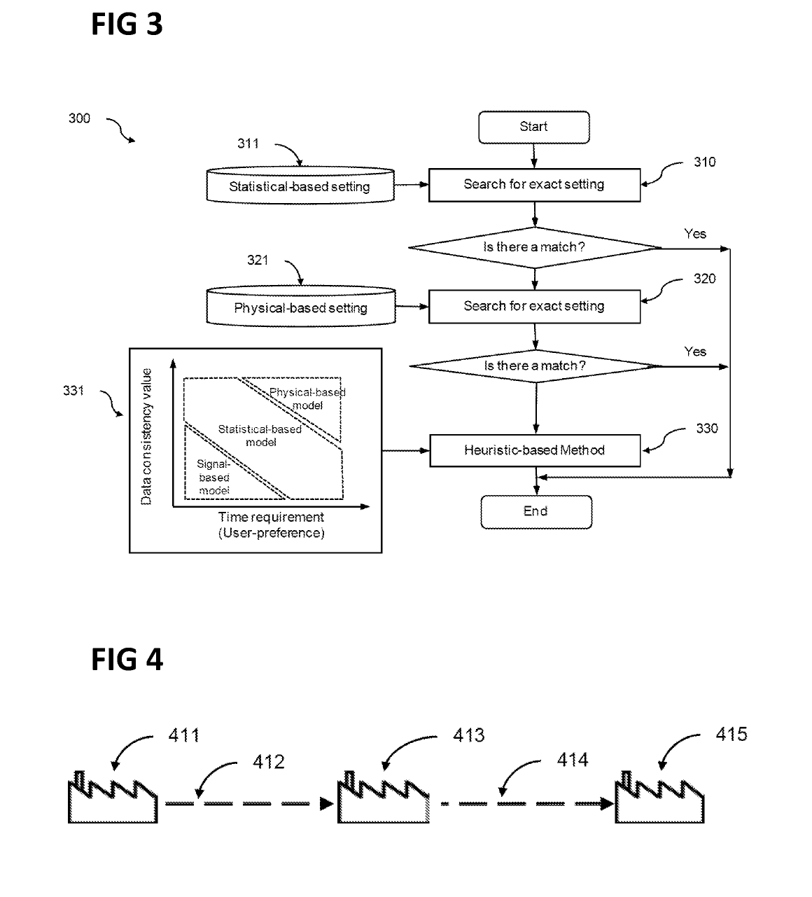

FIG. 3 shows a flow diagram 300 illustrating an example providing of road impact model selection function 260 according to various embodiments. The first stage as defined by functions 310 and 320 may include searching for an exact event setting. The setting can be defined by a combination of a specific product, route and vehicle type. Data table 311 can include or can be a list of all event settings that can be identified from 221 that are related to a statistical-based model. Similarly, data table 321 can include the settings relating to a physical-based model. The order for checking an exact event setting may be decided based on the fact that physical-based model are validated by statistical-based model. The second stage can be provided by a search method using heuristics 330. Function 331 shows an example of a heuristics-based method using dual criteria. If a setting has no exact match is found, a road condition impact model is decided based on the intersection of the data consistency value and time requirement. In 331, the time requirement associated to road condition models can be derived from previous execution times of road impact analysis 130. The execution times of each road condition models are processed to create mapping of time requirement and road condition impact model. This chart can be further extended to tuple representation to handle multiple criteria.

In the following, road impact evaluation on distributed manufacturing according to various embodiments will be described.

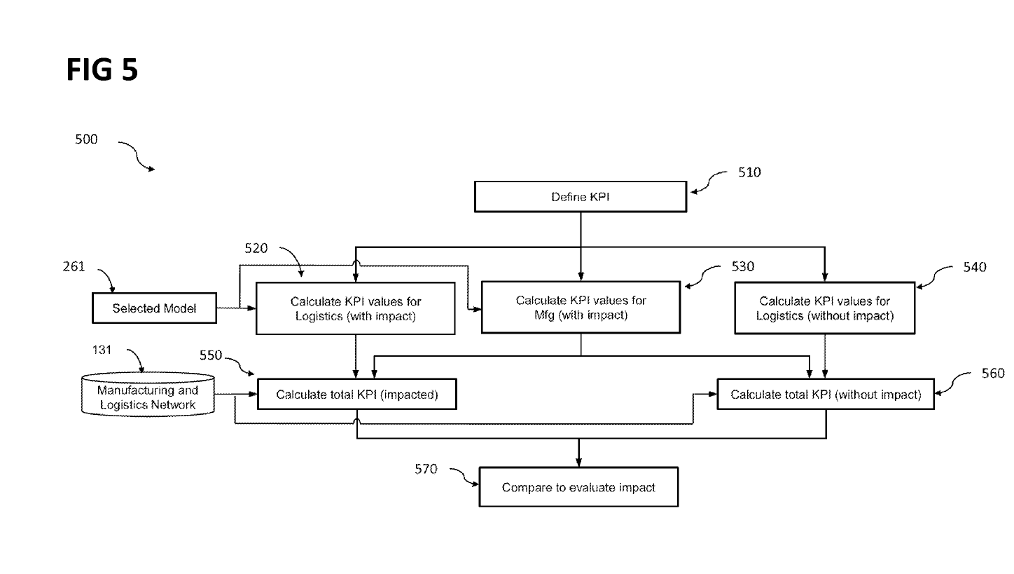

FIG. 4 shows a representation of manufacturing and logistics network in database 131 according to various embodiments. Factory elements 411, 413 and 415 represent manufacturing plants that are geographically separated by road elements 412, and 414. The operation of factory element 411 can impact factory element 413 and subsequently factory element 415. Similarly, the road condition in road element 412 can impact operation of factory elements in both the upstream and downstream parts of the network. For example, if road element 412 caused product damage in a transport of product, the factory element 413 is affected as a direct link and subsequently 415 as a downstream link. On the other hand, factory element 411 has to compensate for the product damage, for example, by increasing product volume on the next delivery cycle. The factory elements can be represented as nodes in a network model while the links connecting these nodes can be an evaluated value depending on the KPI and the impact of road surface condition.

One of the KPIs can be a total manufacturing yield that may be affected by factory elements. For a distributed manufacturing network, a definition of total yield can be extended to logistics network by incorporating road condition impact. For example, each manufacturing plant has individual manufacturing yield. A total manufacturing yield, for example, can be calculated by processing manufacturing yields of factory element 411, factory element 413 and factory element 415 and other conversion values since a product from factory element 411 may processed to another products in factory element 413 and/or factory element 415. This calculation however neglects the fact that some products can be damaged during transportation between manufacturing plants; this is solved by incorporating road elements 412 and 414.

FIG. 5 shows an illustration 500 of providing the impact evaluation function 270 according to various embodiments. The impact evaluation function 270 may evaluate a total performance index of a distributed manufacturing represented in 131 and taking into consideration road condition impact. In function 510, a KPI may be defined. In function 520, a KPI is calculated for Logistics component only by considering road surface condition impacts. In function 530 a KPI is calculated for Manufacturing component only, i.e., factory elements. Subsequently in function 550, a total KPI is calculated for the entire distributed manufacturing by combining logistics and manufacturing components. On the other hand, in function 540 a KPI is calculated by assuming that the road condition is ideal but is useful as a reference for measuring improvement opportunities. Similarly in function 560, a total KPI without impact is calculated by combining the result from manufacturing component only and logistics component. The output values from function 550 and function 560 are compared in function 570, which can be a difference or a ratio of these two values.

In the following, a road impact map for monitoring and simulation according to various embodiments will be described.

According to various embodiments, an example for the road impact-related module 140 may be a road impact map for monitoring and simulation.

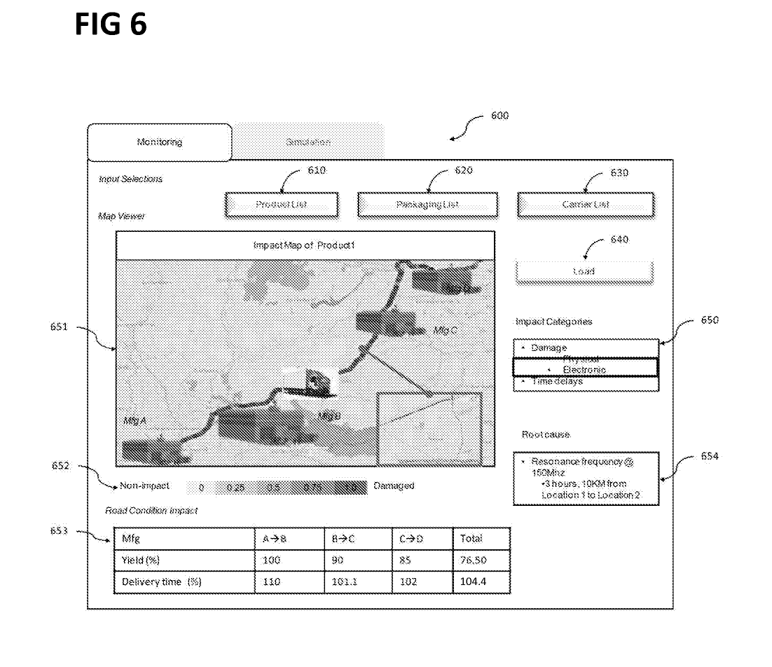

FIG. 6 shows an illustration 600 of a user-interface for monitoring according to various embodiments. A first selection dialog 610 provides a list of products. A second selection dialog 620 provides a list of packaging options. A third selection dialog 630 provides for the carrier list. A combination from these selections can only be allowed based on actual event settings from the synthesized data 211.

By pressing button 640, the data base 211 (via the application interface 230) may be queried of the event settings that match the input selection. A result of the query is to provide a list of impact categories list 650. This list is a derived data by processing incident data that are associated to an event setting. By selecting an item on this list, an impact map is displayed in map viewer 651. The map can show a visualization of manufacturing and logistics network showing the factory elements and road elements. The road elements can be color-coded based on road impact of the selected setting, or can be represented by patterns or markers associated to specific road impacts. The corresponding impacts values of the color codes can be shown in legend 652. Table 653 provides a summary of the road condition impact. List 654 can be further information to describe the cause of the road condition impact.

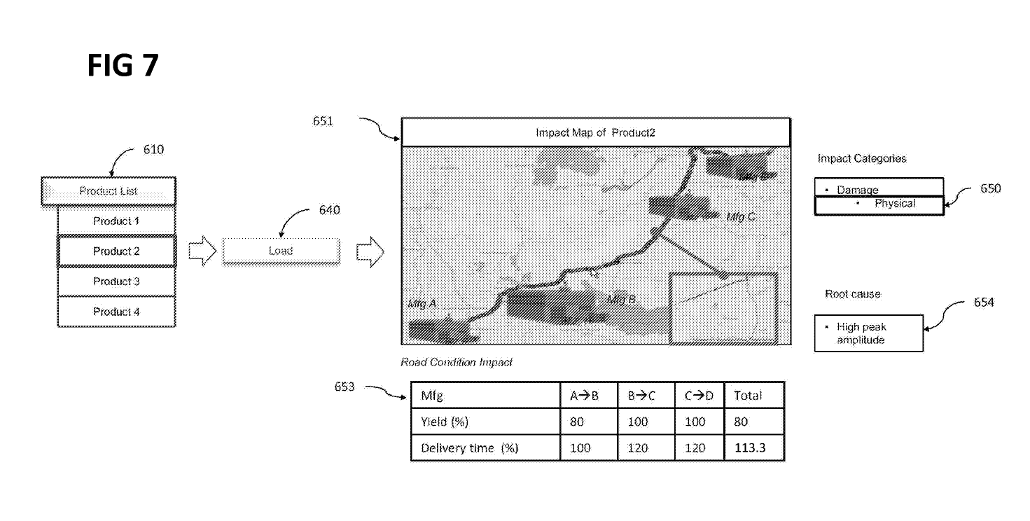

FIG. 7 shows a transition diagram when the first selection dialog 610 is changed from Product 1 to Product 2. After selecting Product 2, and assuming the same setting for the second dialog 620 and the third selection dialog 630, button 640 can be pressed to effect the change in the selection. Consequently, a list of impact categories is displayed in the impact categories list 650. After selecting an item in the impact categories list 650, an impact map for Product 2 is displayed in the map viewer 651 and the corresponding road condition impact summary is shown in table 653.

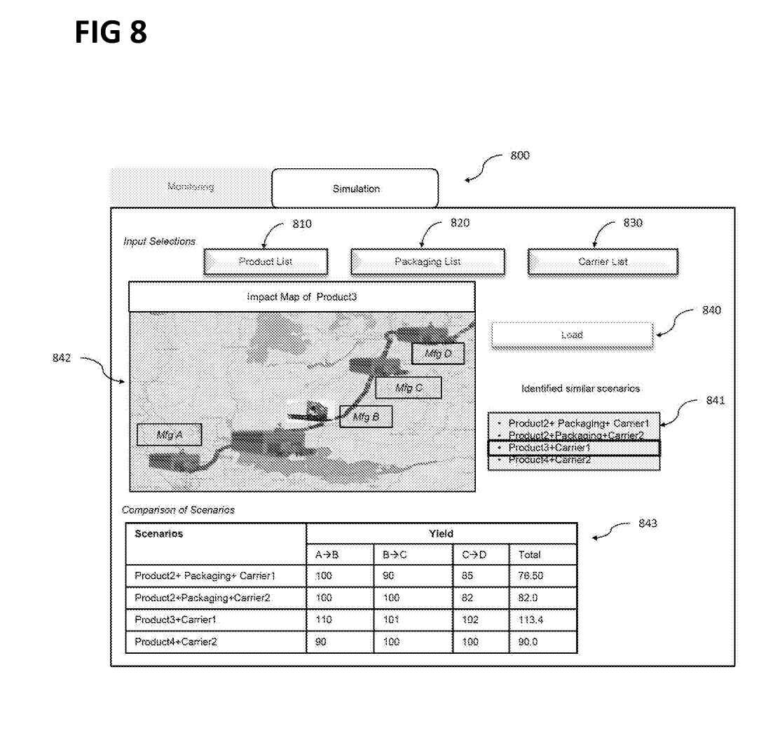

FIG. 8 shows an illustration 800 of an implementation of a simulation part of road impact map according to various embodiments. The functions of dialogs are similar to that of illustration 600 shown in FIG. 6. A first dialog 810 for a list of products, a second dialog 820 for packaging list, and a third dialog 830 for a list of carrier types are provided. Any selections from this dialogs can be allowed even if no factual data or actual collected data of the same event setting is conducted. By pressing button 840, a setting that is similar to the selected input is queried to data base 211. The implementation for similarity criteria may be implemented as a functional part of the simulation part shown in the illustration 800. The identified similar scenarios are then shown in list view 841. By selecting an item in 841, the corresponding road impact map is displayed in map viewer 842. Table 843 provides a comparison of the scenarios listed in the list view 841. The table 843 can include one or all the KPIs for comparison purposes.

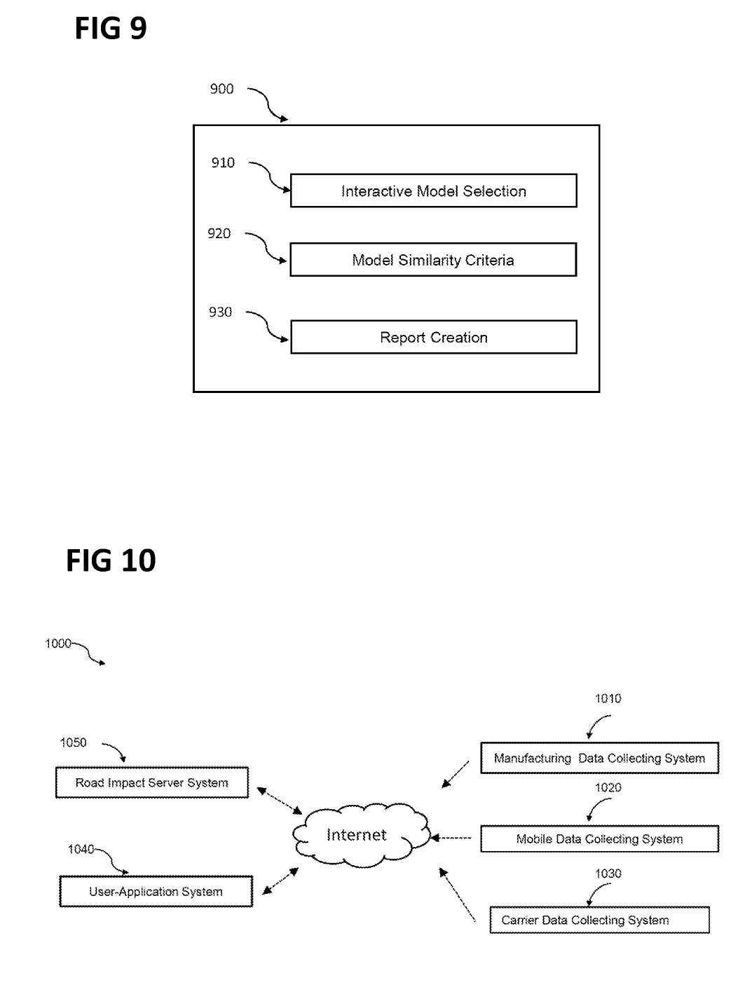

FIG. 9 shows a list 900 of additional functions that can be provided for monitoring and simulation functions for road impact map according to various embodiments. Interactive model selection function 910 can be capable of handling user inputs from user interface from either monitoring or simulation like the first dialog 810, the second dialog 820, and the third dialog 830. It sends queries to data base 211 and stores query results. Model similarity criteria function 920 can be a dedicated function for simulation to select a group of road impact models with settings similar to a user input selection. Report creation function 930 can create a tabular report and map visualization for the road impact map.

In the following, an implementation of system configuration for road impact evaluation in a distributed network according to various embodiments will be described.

FIG. 10 shows an illustration 1000 of an implementation of the system configuration for various modules (for example the data sources module 110, impact model generation module 120, road impact analysis module 130, and the road impact-related application 140 according to various embodiments. The data for module 110 can come from at least one manufacturing data collecting system 1010, mobile data collecting system 1020, and carrier data collecting system 1030. The manufacturing data collecting system 1010 can be a data source of manufacturing data 111, while mobile data collecting system 1020 can be configured to function as a data source for carrier in-Transit data 112 as well as logistics data 113. Similarly, the carrier data collecting system 1030 can be data sources for carrier in-transit data 112 and logistics data 113. User application system 1040 is the system for module 140. Road impact server system 1050 is the system for module 120 and module 130. The various systems may be connected to the internet, like illustrated in FIG. 10.

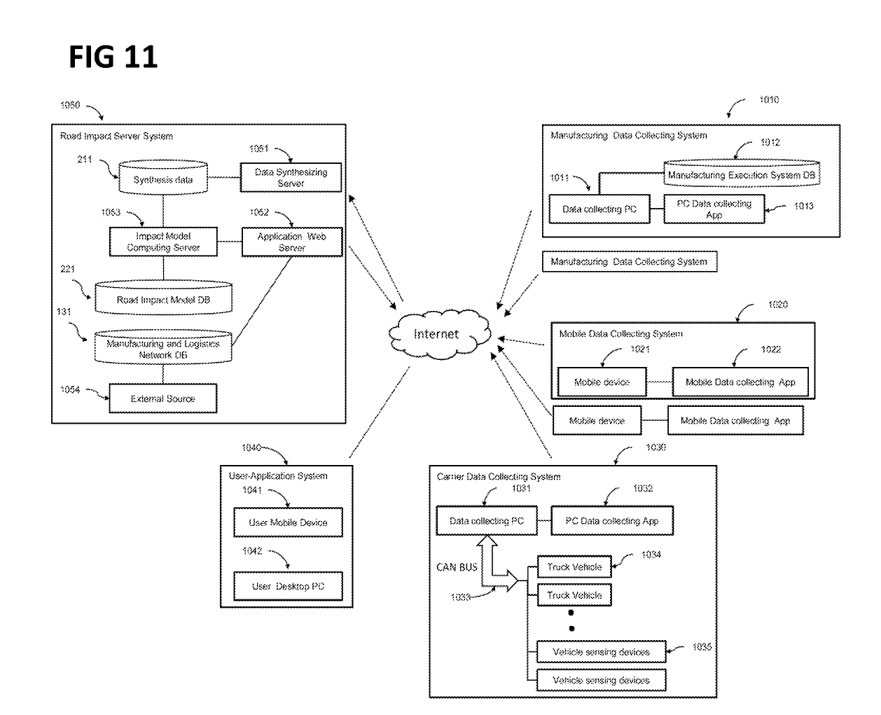

FIG. 11 shows a detailed implementation of the system configuration of FIG. 10 according to various embodiments. In the manufacturing data collecting system 1010, a PC (personal computer) data collecting app (application) 1013 is installed in a data collecting PC 1011 which collects data from manufacturing execution system DB (database) 1012. In the mobile data collecting system 1020, a mobile device 1021 which may be equipped with sensing elements is installed with mobile data collecting app 1022. This setup can be utilized as a sensing device 1035 for vehicle trucks. In the carrier data collecting system 1030, data collecting PC 1031 is installed with a PC data collecting app 1032 to collected data from CAN (controller area network) BUS 1033, which is a vehicle data communication bus for truck vehicle 1034, other truck vehicles, and vehicle sensing devices 1035. These data from the manufacturing data collecting system 1010, the mobile data collecting system 1020, the carrier data collecting system 1030 can be sent to the road impact server system 1050 via the Internet.

In the road impact server system 1050, incoming data is processed by data processing server 1051 and the processed data is stored in 211. The model generation, selection and analysis is conducted in impact model computing server 1053. On the other hand, application web server 1052 is an application server that handles request from system users in user-application side 1040 (which may include a user mobile device 1041 and/or a user desktop PC 1042). The data in 131 can be derived from an external source 1054.

According to various embodiments, a model determination device may be provided. The model determination device may include: a receiving circuit configured to receive manufacturing data related to a product and carrier data related to transporting the product; and a determination circuit configured to determine a model of an impact of the transporting of the product based on the manufacturing data and based on the carrier data.

According to various embodiments, the manufacturing data may include or may be information on at least one of an identifier of the product, a resonant frequency of the product, a stress limit of the product, a volume of the product, or a shipping date of the product.

According to various embodiments, the carrier data may include or may be at least one of carrier in-transit data, sensing signals, a time related to the transporting, a location related to the transporting, information on a vehicle used for the transporting, a sensed vibration during the transporting, or an orientation of the product during transporting.

According to various embodiments, the receiving circuit may further be configured to receive logistics data related to the transporting. According to various embodiments, the determination circuit may be configured to determine the model further based on the logistics data.

According to various embodiments, the logistics data may include or may be at least one of routing information of the transporting, or incident information of the transporting.

According to various embodiments, the receiving circuit may further be configured to receive environment data related to the transporting. According to various embodiments, the determination circuit may be configured to determine the model further based on the environment data.

According to various embodiments, the environment data may include or may be at least one of traffic information or temperature information.

According to various embodiments, the determination circuit may be configured to establish the model.

According to various embodiments, the determination circuit may be configured to select a model from a plurality of dissimilar models of a plurality of categories.

According to various embodiments, the determination circuit may be configured to select the model based on at least one of data source quality or user input preference.

According to various embodiments, the plurality of categories may include or may be at least two of a category of statistical models, a category of statistical-based models, a category of physical-based models, or a category of signal-based models.

According to various embodiments, the model determination device may further include an evaluation circuit configured to evaluate a key performance indicator of distributed manufacturing based on the model.

According to various embodiments, the key performance indicator may include or may be at least one of a yield of products or a production time for products.

According to various embodiments, the model determination device may further include a prescribing circuit configured to prescribe a condition for the transporting based on the model.

According to various embodiments, the condition may include or may be at least one of a packaging for the product or a speed of the transporting.

According to various embodiments, a model determination method may be provided. The model determination method may include: receiving manufacturing data related to a product and carrier data related to transporting the product; and determining a model of an impact of the transporting of the product based on the manufacturing data and based on the carrier data.

According to various embodiments, the manufacturing data may include or may be information on at least one of an identifier of the product, a resonant frequency of the product, a stress limit of the product, a volume of the product, or a shipping date of the product.

According to various embodiments, the carrier data may include or may be at least one of carrier in-transit data, sensing signals, a time related to the transporting, a location related to the transporting, information on a vehicle used for the transporting, a sensed vibration during the transporting, or an orientation of the product during transporting.

According to various embodiments, the model determination method may further include receiving logistics data related to the transporting. According to various embodiments, the model may be determined further based on the logistics data.

According to various embodiments, the logistics data may include or may be at least one of routing information of the transporting, or incident information of the transporting.

According to various embodiments, the model determination method may further include receiving environment data related to the transporting. According to various embodiments, the model may be determined further based on the environment data.

According to various embodiments, the environment data may include or may be at least one of traffic information or temperature information.

According to various embodiments, determining the model may include or may be establishing the model.

According to various embodiments, determining the model may include or may be selecting a model from a plurality of dissimilar models of a plurality of categories.

According to various embodiments, selecting the model may include or may be selecting the model based on at least one of data source quality or user input preference.

According to various embodiments, the plurality of categories may include or may be at least two of a category of statistical models, a category of statistical-based models, a category of physical-based models, or a category of signal-based models.

According to various embodiments, the model determination method may further include evaluating a key performance indicator of distributed manufacturing based on the model.

According to various embodiments, the key performance indicator may include or may be at least one of a yield of products or a production time for products.

According to various embodiments, the model determination method may further include prescribing a condition for the transporting based on the model.

According to various embodiments, the condition may include or may be at least one of a packaging for the product or a speed of the transporting.

The devices (in other words: systems) and methods according to various embodiments may be utilized for developing specific applications for manufacturing, carrier companies, and logistics service providers.

According to various embodiments, the devices and methods may be applied in a vehicle speed recommendation system. The devices and methods may be utilized in a system that takes into consideration controlling truck velocity and acceleration to achieve minimal product damage. This vehicle speed recommendation can further provide a fleet scheduling in a group of truck vehicles such that minimal lead time and minimal product damage can be achieved.

According to various embodiments, the devices and methods may be applied in a packaging recommendation application where in an appropriate packaging can be suggested based on the detected surface condition.

It will be understood that in the description above, whenever reference is made to a “function” or to a “module”, both the respective steps in a method, in which the “function” or the functionality of the “module” is carried out, and the respective circuit configured to carry out the “function” or the functionality of the “module” is addressed.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

1. A model determination device comprising:
a receiving circuit configured to receive manufacturing data related to a product and carrier data related to transporting the product; and
a determination circuit configured to determine a model of an impact of the transporting of the product based on the manufacturing data and based on the carrier data.

2. The model determination device of claim 1,
wherein the manufacturing data comprises information on at least one of an identifier of the product, a resonant frequency of the product, a stress limit of the product, a volume of the product, or a shipping date of the product.

3. The model determination device of claim 1,
wherein the carrier data comprises at least one of carrier in-transit data, sensing signals, a time related to the transporting, a location related to the transporting, information on a vehicle used for the transporting, a sensed vibration during the transporting, or an orientation of the product during transporting.

4. The model determination device of claim 1,
wherein the receiving circuit is further configured to receive logistics data related to the transporting; and
wherein the determination circuit is configured to determine the model further based on the logistics data.

5. The model determination device of claim 4,
wherein the logistics data comprises at least one of routing information of the transporting, or incident information of the transporting.

6. The model determination device of claim 1,
wherein the receiving circuit is further configured to receive environment data related to the transporting; and
wherein the determination circuit is configured to determine the model further based on the environment data.

7. The model determination device of claim 6,
wherein the environment data comprises at least one of traffic information or temperature information.

8. The model determination device of claim 1,
wherein the determination circuit is configured to establish the model.

9. The model determination device of claim 1,
wherein the determination circuit is configured to select a model from a plurality of dissimilar models of a plurality of categories.

10. The model determination device of claim 9,
wherein the determination circuit is configured to select the model based on at least one of data source quality or user input preference.

11. The model determination device of claim 9,
wherein the plurality of categories comprises at least two of a category of statistical models, a category of statistical-based models, a category of physical-based models, or a category of signal-based models.

12. The model determination device of claim 1, further comprising:
an evaluation circuit configured to evaluate a key performance indicator of distributed manufacturing based on the model.

13. The model determination device of claim 12,
wherein the key performance indicator comprises at least one of a yield of products or a production time for products.

14. The model determination device of claim 1, further comprising:
a prescribing circuit configured to prescribe a condition for the transporting based on the model.

15. The model determination device of claim 14,
wherein the condition comprises at least one of a packaging for the product or a speed of the transporting.

16. A model determination method comprising:
receiving manufacturing data related to a product and earner data related to transporting the product; and
determining a model of an impact of the transporting of the product based on the manufacturing data and based on the carrier data.
